(19) United States
(12) Patent Application Publication
(10) Pub. No.: US 2023/0365401 A1
(43) Pub. Date: Nov. 16, 2023

(54) MICRO-ELECTROMECHANICAL SYSTEMS (MEMS) DEVICE AND NOISE CANCELLATION METHOD

(71) Applicants: HUAWEI TECHNOLOGIES CO., LTD., Shenzhen (CN); FRAUNHOFER-GESELLSCHAFT ZUR FOERDERUNG DER ANGEWANDTEN FORSCHUNG E.V., Munich (DE)

(72) Inventors: Ulrich HOFMANN, Itzehoe (DE); Thomas Von WANTOCH, Itzehoe (DE); Christian JANICKE, Itzehoe (DE); Leon POHL, Itzehoe (DE); Stephan MARAUSKA, Itzehoe (DE); Thomas KNIELING, Itzehoe (DE); Frank SENGER, Itzehoe (DE); Joerg ALBERS, Itzehoe (DE)

(21) Appl. No.: 18/196,825

(22) Filed: May 12, 2023

Related U.S. Application Data
(63) Continuation of application No. PCT/EP2020/082098, filed on Nov. 13, 2020.

(51) Int. Cl. B81B 7/02; B81C 1/00; G10K 11/178

(52) U.S. Cl. CPC B81B 7/02; B81C 1/00198; G10K 11/178; G10K 2210/129; B81B 2201/032; B81B 2207/015; B81B 2207/09; B81C 2203/03

(57) ABSTRACT

There is provided a micro-electromechanical system (MEMS) device (102, 200, 300, 404) for cancelling noise generated by oscillation of a movable micro-electromechanical system (MEMS) element (104, 204, 304, 406). The micro-electromechanical system (MEMS) device (102, 200, 300, 404) includes the movable micro-electromechanical system (MEMS) element (104, 204, 304, 406), an actuator (106, 208, 306, 408), a controller (108, 410) and a movable noise cancelling element (110, 202, 312, 412). The controller (108, 410) provides electrical signals to drive the actuator (106, 208, 306, 408) and the movable noise cancelling element (110, 202, 312, 412) in a way to cancel the noise generated in the micro-electromechanical system (MEMS) device (102, 200, 300, 404) by oscillation of the movable MEMS element (104, 204, 304, 406). The movable noise-cancelling element (110, 202, 312, 412) produces anti-phase noise based on the electrical signals received from the controller (108, 410) to cancel noise caused by oscillation of the movable MEMS element (104, 204, 304, 406) based on the control signals received from the controller (108, 410).

### TECHNICAL FIELD

The present disclosure relates generally to a micro-electromechanical systems (MEMS) device, and more particularly to a noise cancelling method for the micro-electromechanical system (MEMS) device.

### BACKGROUND

A microelectromechanical system (MEMS) is a high precision system that is used to sense, control, or actuate on very small scales by combining mechanical, electrical, magnetic, thermal and/or other physical phenomena. Microelectromechanical systems (MEMS) are utilised in biomedical applications, optical applications, acoustic application etc. In some applications, the microelectromechanical system (MEMS) is configured as a movable component to provide high precision results. For example, fast-moving parts of the microelectromechanical system (MEMS) such as optical elements, e.g. MEMS mirrors, are configured to oscillate to deflect light controllably in optical applications such as in projectors, for example for virtual reality or augmented reality applications. The movement of a MEMS element can lead to vibration of the component or system incorporating the MEMS element, and such vibration can be disturbing for users if the vibration is sensed through touch or if the vibration gives rise to audible noise. MEMS element vibration is a particular problem in virtual reality or augmented reality devices such as glasses, goggles or helmets that incorporate one or more MEMS element, because such devices tend to be head-mounted and consequently vibration and audible noise may more readily be sensed by the wearer. It will be appreciated however that vibration and noise from the movement of MEMS elements may cause a nuisance even when the MEMS elements form part of devices that are not head or even body-mounted, so that even free-standing devices may suffer from troublesome vibration or noise caused by the movement of MEMS elements.

Existing technology vacuum encapsulates the fast-moving MEMS elements to reduce the likelihood that noise will reach human ears located in the vicinity of the fast-moving microelectromechanical system (MEMS) parts. However, this encapsulation requires increases the size of the encapsulated parts and adds weight, both factors that negatively impact user experience, as well of course of increasing costs. Moreover, even though vacuum encapsulation of the moveable MEMS elements may reduce the amount of audible noise generated, vibration caused by movement of the MEMS elements may be mechanically coupled to parts or elements that are not vacuum encapsulated and which can therefore create audible noise, as well as potentially leading to a user sensing mechanically coupled vibration. These latter problems are of particular concern in the case of head-mounted systems that use moveable MEMS elements.

Therefore, there arises a need to address the aforementioned technical drawbacks in existing technologies to improve the user experience of a device which includes microelectromechanical system (MEMS) parts.

### SUMMARY

It is an object of the present disclosure to reduce the impact of vibration generated in a micro-electromechanical systems (MEMS) device while avoiding one or more disadvantages of prior art approaches.

This object is achieved by features of the independent claims. Further implementation forms are apparent from the dependent claims, the description, and the figures.

According to a first aspect, there is provided a micro-electromechanical systems, MEMS, device including:
a movable MEMS element;
an actuator operable to move the movable MEMS element;
and a controller to control the actuator to cause controlled movement of the movable MEMS element;
the device additionally comprising:
a movable noise-cancelling element arranged to be driven under the control of the controller to produce anti-phase noise to cancel noise caused by oscillation of the movable MEMS element.

The advantage of this aspect is that noise caused by movement of the movable MEMS element can be cancelled, reducing the effects of the noise and improving user experience, particularly in the case that the MEMS device is a wearable device.

In a first possible implementation form of the MEMS device of the first aspect, the movable MEMS element and the actuator are formed on a common semiconductor substrate. This enables more efficient coupling therebetween, as well as potentially a very compact structure.

In a second possible implementation form of the MEMS device of the first aspect as such or the first possible implementation form of the first aspect, the actuator and the movable MEMS element are packaged together in a common hermetic package, and the movable noise-cancelling element is located outside of the common hermetic package. Any hermetic package is preferably evacuated to form a near vacuum.

In a third possible implementation form of the MEMS device of the first aspect, the movable MEMS element is a MEMS element of a MEMS structure, and the actuator is not an element of the MEMS structure that provides the movable MEMS element.

In a fourth possible implementation form of the MEMS device of the third possible implementation form of the first aspect, the movable noise-cancelling element and the actuator are mounted on a common substrate. The use of a common substrate enables the movable noise-cancelling element to cancel noise effectively, and in particular to better cancel noise caused by movement of the actuator.

In a fifth possible implementation form of the MEMS device of the fourth possible implementation form of the first aspect, the movable MEMS element is mounted on the actuator. When the MEMS element is mounted on the actuator, the actuator controls the movement of the movable MEMS element.

In a sixth possible implementation form of the MEMS device of the third possible implementation form of the first aspect, the actuator is a piezoelectric element.

In a seventh possible implementation form of the MEMS device of the first aspect as such or the first possible implementation form or the second possible implementation form of the first aspect, the movable noise-cancelling element is a MEMS element.

In an eighth possible implementation form of the MEMS device of the seventh possible implementation form when combined with the first possible implementation form of the first aspect, the movable noise-cancelling element is also formed on the common semiconductor substrate. The movable noise-cancelling element occupies less space in the MEMS device when it is formed on the common semiconductor substrate.

In a ninth possible implementation form of the MEMS device of the first aspect as such or according to any of the preceding implementation forms of the first aspect, the movable noise-cancelling element is a piezoelectric element.

In a tenth possible implementation form of the MEMS device of the ninth possible implementation form when combined with the sixth possible implementation form of the first aspect, the controller is configured to feed the actuator and the movable noise-cancelling element with the same electrical signals but 180 degrees out of phase. By using the same electrical signals, 180 degrees out of phase, the processing burden on the controller is reduced and the effectiveness of the noise cancellation improved.

In an eleventh possible implementation form of the MEMS device of the first aspect as such or according to any of the preceding implementation forms from first to ninth of the first aspect, the MEMS device is provided in combination with a transducer that is arranged to provide the controller with signals derived from noise generated by the movable MEMS element.

In a twelfth possible implementation form of the MEMS device of the eleventh possible implementation form of the first aspect, the controller is configured to generate signals to drive the movable noise-cancelling element based on the signals received from the transducer.

In a thirteenth possible implementation form of the MEMS device of the first aspect as such or according to any of the preceding implementation forms of the first aspect, the movable MEMS element is an optical element.

In a fourteenth possible implementation form of the MEMS device of the thirteenth possible implementation form of the first aspect, the MEMS device is provided in combination with a sound-confining enclosure which surrounds the MEMS device, the sound-confining enclosure defining an aperture through which light can pass from the movable optical MEMS element.

In a fifteenth possible implementation form of the MEMS device of the fourteenth possible implementation form of the first aspect, the arrangement is such that noise from the movable optical MEMS element and anti-phase noise from the movable noise-cancelling element can emerge from the sound-confining enclosure through the aperture to effect noise-cancellation in a direction in which light passes from the movable optical MEMS element through the aperture.

In a sixteenth possible implementation form of the MEMS device of the first aspect as such or according to any of the preceding implementation forms of the first aspect, the movable noise-cancelling element and the controller are configured to also produce anti-phase noise to cancel noise caused by movement of the actuator.

According to a second aspect, there is provided a wearable device including one or more MEMS devices according to the first aspect or any of its possible implementations.

In a first possible implementation form of the wearable device of the second aspect, the wearable device is configured as a Virtual Reality, VR, or Augmented Reality, AR, display. The wearable device optionally includes at least one of glasses, earphones, helmets, watches, smartphones or tabs etc. The one or more MEMS devices in the augmented reality or virtual reality display improves the user experience of the AR/VR display when using it.

According to a third aspect, there is provided a noise cancellation method for a micro-electromechanical system, MEMS, device, the method including:
generating noise by applying a signal to an actuator of the MEMS device to cause controlled movement of a movable MEMS element of the MEMS device; and
applying a noise cancellation signal to a movable noise-cancelling element of the MEMS device to produce anti-phase noise to cancel the noise caused by oscillation of the movable MEMS element.

This method enables the cancellation of the noise generated in the micro-electromechanical system (MEMS) device by producing anti-phase noise. This method helps to improve the user experience by achieving good cancelation of the noise generated by the movable MEMS element.

In a first possible implementation form of the third aspect, the signal applied to the actuator is the same as the noise cancellation signal that is applied to the movable noise-cancelling element but 180 degrees out of phase.

In a second possible implementation form of the third aspect, the method includes using a transducer to produce electrical signals based on the noise generated by movement of the movable MEMS element; and
processing the electrical signals produced by the transducer to produce the noise cancellation signal that is applied to the noise-cancelling element. The transducer may convert the electrical signals into a mechanical displacement or stress based on a piezoelectric effect.

According to a fourth aspect, there is provided a method of making a micro-electromechanical systems (MEMS) device including a noise-cancelling function, the method including:
forming a movable MEMS element;
forming a MEMS actuator operable to move the movable MEMS element; and
forming a movable noise-cancelling MEMS element that is drivable to produce anti-phase noise to cancel noise caused by oscillation of the movable MEMS element; wherein the three forming operations are performed on the same semiconductor substrate.

This method enables the formation of MEMS devices which are compact and which provide good noise cancellation performance. The MEMS device that is fabricated by the method of the fourth aspect can be formed in a compact assembly which has good noise cancellation making it particularly suitable for use in applications such as the AR/VR applications.

According to the fifth aspect, there is provided a method of making a micro-electromechanical systems (MEMS) device including a noise-cancelling function, the method including
coupling a movable MEMS element to an external actuator operable to move the movable MEMS element;
bonding the external actuator to a substrate; and
bonding a movable noise-cancelling element to the substrate, the movable noise-cancelling element being drivable to produce anti-phase noise to cancel noise caused by oscillation of the movable optical MEMS element.

The MEMS device that is made by the method of the fifth aspect can be formed in a compact assembly which has good noise cancellation making it particularly suitable for use in applications such as the AR/VR applications.

In a first possible implementation form of the fifth aspect, the substrate is configured to mechanically decouple the external actuator from the movable noise-cancelling element.

These and other aspects of the present disclosure will be apparent from the drawings and the embodiment(s) described below.

### BRIEF DESCRIPTION OF THE DRAWINGS

Embodiments of the present disclosure will now be described, by way of example only, with reference to the following diagrams in which:

FIG. 1 is a schematic illustration of a micro-electromechanical systems (MEMS) device that has a noise cancelling function in accordance with an embodiment of the present disclosure;

FIG. 2 is a schematic illustration of a micro-electromechanical systems (MEMS) device with a noise-cancelling element in accordance with an embodiment of the present disclosure;

FIG. 3 is a schematic illustration of noise (air oscillation) cancellation by a micro-electromechanical system (MEMS) device in accordance with an embodiment of the present disclosure;

FIG. 4 is a schematic illustration of an example wearable device with a micro-electromechanical systems (MEMS) device for cancelling a noise generated by oscillation of a movable micro-electromechanical systems (MEMS) element in accordance with an embodiment of the present disclosure;

FIG. 5 is a flow diagram of a method of cancelling a noise for a micro-electromechanical systems (MEMS) device in accordance with an embodiment of the present disclosure;

FIG. 6 is a flow diagram of an exemplary method of making a micro-electromechanical systems (MEMS) device with a noise cancelling function in accordance with an embodiment of the present disclosure; and

FIG. 7 is a flow diagram of an exemplary method of making a micro-electromechanical system (MEMS) device with a noise cancelling function in accordance with an embodiment of the present disclosure.

### DETAILED DESCRIPTION

Embodiments of the present disclosure provide a micro-electromechanical systems (MEMS), device, and a method to reduce the impact of vibration generated in a micro-electromechanical systems (MEMS) device and improve the user experience.

To make the solutions of the present disclosure more comprehensible for a person skilled in the art, the following clearly and completely describes the technical solutions in the embodiments of the present disclosure with reference to the accompanying drawings in the embodiments of the present disclosure. The described embodiments are merely a part rather than all of the embodiments of the present invention. All other embodiments obtained by a person of ordinary skill in the art based on the embodiments of the present disclosure without creative efforts shall fall within the protection scope of the present application.

In order to help understand embodiments of the present disclosure, several terms that will be introduced in the description of the embodiments of the present disclosure are defined herein first.

Terms such as “a first”; “a second”, “a third”, and “a fourth” (if any) in the summary, claims, and foregoing accompanying drawings of the present disclosure are used to distinguish between similar objects and are not necessarily used to describe a specific sequence or order. It should be understood that the terms so used are interchangeable under appropriate circumstances, so that the embodiments of the present disclosure described herein are, for example, capable of being implemented in sequences other than the sequences illustrated or described herein. Furthermore, the terms “include” and “have” and any variations thereof, are intended to cover a non-exclusive inclusion. For example, a process, a method, a system, a product, or a device that includes a series of steps or units, is not necessarily limited to expressly listed steps or units, but may include other steps or units that are not expressly listed or that are inherent to such process, method, product, or device.

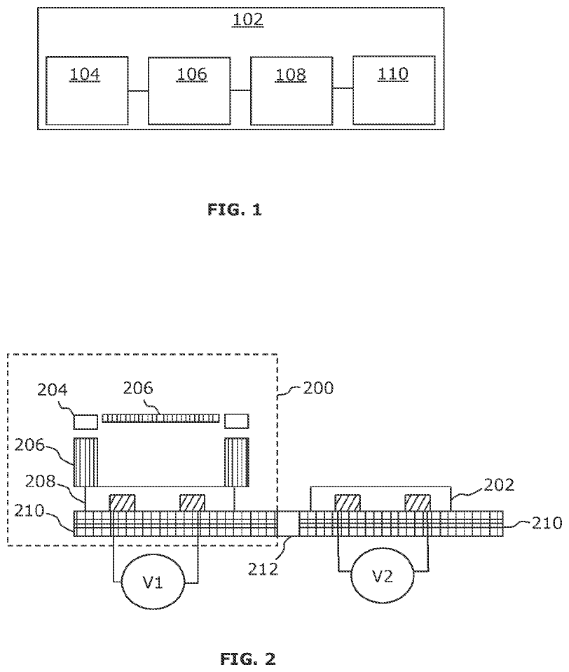

FIG. 1 is a schematic illustration of a micro-electromechanical systems (MEMS) device 102 that has a noise cancelling function in accordance with an embodiment of the present disclosure. The micro-electromechanical systems (MEMS) device 102 includes a movable MEMS element 104, an actuator 106, a controller 108 and a movable noise-cancelling element 110. The actuator 106 is operable to move the movable MEMS element 104. The controller 108 controls the actuator 106 to cause controlled movement of the movable MEMS element 104. The movable noise-cancelling element 110 is arranged to be driven under the control of the controller 108 to produce anti-phase noise to cancel noise caused by oscillation of the movable MEMS element 104.

The movable MEMS element 104 is connected with the actuator 106. The controller 108 provides electrical signals to the actuator 106 for controlling movement of the movable MEMS element 104. The actuator 106 converts the electrical signals into motion and enables movement of the movable MEMS element 104 based on the electrical signals received from the controller 108. The actuator 106 may act as a transducer to convert electrical energy into a mechanical displacement or stress based on a piezoelectric effect. The movable noise-cancelling element 110 is optionally connected with the actuator 106. The controller 108 optionally includes a microcontroller (MCU) or a microprocessor or a digital signal processor (DSP).

Frequencies of the noise generated by the movable MEMS element 104 (e.g. a MEMS mirror) may be equal to driving/operating frequencies of the movable MEMS element 104, and also be equal eigen-frequencies of MEMS components. The MEMS components may include the actuator 106 and/or the movable noise cancelling element 110.

The person skilled in the art will understand that the frequencies of the noise to be cancelled are not in the wide frequency range of 20 Hz to 20,000 Hz (the typical maximum frequency range of human hearing), but in one or two specified frequencies, and these may be predicted from the design of the MEMS components.

According to a first embodiment, the movable MEMS element 104 and the actuator 106 are formed on a common semiconductor substrate. The movable MEMS element 104 and the actuator 106 are optionally packaged together in a common hermetic package, and the movable noise-cancelling element 110 may be located outside of the common hermetic package.

According to a second embodiment, the movable MEMS element 104 is a MEMS element of a MEMS structure, and the actuator 106 is not an element of the MEMS structure that provides the movable MEMS element 104.

The movable noise-cancelling element 110 and the actuator 106 are optionally mounted on a common substrate when the actuator 106 is not an element of the MEMS structure that provides the movable MEMS element 104. The movable MEMS element 104 is optionally mounted on the actuator 106 when the movable noise-cancelling element 110 and the actuator 106 are mounted on the common substrate. The actuator 106 is optionally a piezoelectric element.

The movable noise-cancelling element 110 is optionally a MEMS element. The movable noise cancelling-element 110 may be formed on the common semiconductor substrate when the movable MEMS element 104 and the actuator 106 are formed on the common semiconductor substrate and the movable noise-cancelling element 110 is the MEMS element. The movable noise-cancelling element 110 is optionally a piezoelectric element.

According to a third embodiment, when the actuator 106 is a piezoelectric element, the controller 108 is configured to feed the actuator 106 and the movable noise-cancelling element 110 with the same electrical signals but 180 degrees out of phase. The controller 108 provides the movable noise-cancelling element 110 with electrical signals to enable the generation of noise-cancelling vibrations. Typically, this involves supplying signals which are 180 degrees out of phase from the control signals provided to the actuator 106.

The micro-electromechanical systems (MEMS) device 102 is optionally provided in combination with a transducer that is arranged to provide the controller 108 with signals derived from noise generated by the movable MEMS element 104. The controller 108 may be configured to generate signals to drive the movable noise-cancelling element 110 based on the signals received from the transducer.

According to a fourth embodiment, the movable MEMS element 104 is optionally an optical element. When the movable MEMS element 104 is the optical element, the micro-electromechanical systems (MEMS) device 102 optionally works in combination with a sound-confining enclosure which surrounds the MEMS device 102. The sound-confining enclosure defines an aperture through which light can pass from the movable optical MEMS element. This arrangement is such that noise from the movable optical MEMS element and anti-phase noise from the movable noise-cancelling element 110 can emerge from the sound-confining enclosure through the aperture to effect noise-cancellation in a direction in which light passes from the movable optical MEMS element through the aperture to provide effective noise cancellation.

According to a fifth embodiment, the movable noise-cancelling element 110 and the controller 108 are configured to also produce anti-phase noise to cancel noise caused by movement of the actuator 106.

The movable MEMS element 104 may include at least one of a mirror, a grating, a prism or an optical source. The movable MEMS element 104 may be the whole or elements of a lens, prism, grating, mirrors, light-emitting diode, modulator, or photodetector. The movable MEMS element 104 is optionally placed near the actuator 106.

FIG. 2 is a schematic illustration of an micro-electromechanical systems (MEMS) device 200 with a movable noise-cancelling element 202 in accordance with an embodiment of the present disclosure. The micro-electromechanical system (MEMS) device 200 is shown without encapsulation, and hermetic encapsulation may or may not be provided. The micro-electromechanical system (MEMS) device 200 includes a movable MEMS element 204, an actuator 208, a controller and a movable noise-cancelling element 202. The actuator 208 is operable to move the movable MEMS element 204. The controller controls the actuator 208 to cause controlled movement of the movable MEMS element 204. The movable noise-cancelling element 202 is arranged to be driven under the control of the controller to produce anti-phase noise to cancel noise caused by oscillation of the movable MEMS element 204.

The movable MEMS element 204 may include a μ-mirror chip that is placed near to the actuator 208 using distance holders 206. The actuator 208 may include a mirror actuation device (MAD) and the MAD may be a piezoelectric device. The actuator 208 obtains electrical signals from at least one of the controller or an electrical source (V1 and V2) that is controlled by the controller. The controller may include a microcontroller (MCU) or a microprocessor or a digital signal processor (DSP).

The actuator 208 is operable to control the movement of the movable MEMS element 204. The movable MEMS element 204 optionally includes an optical element. The optical element may include at least one of a mirror, grating, prism or an optical source. The optical element may be the whole or elements of a lens, prism, grating, mirrors, light-emitting diode, modulator, or photodetector. The optical element (e.g. a mirror) is typically placed near to the actuator 208. The movable MEMS element 204, the actuator 208 and the movable noise cancelling-element 202 are optionally formed on a common semiconductor substrate 210.

The movable noise cancelling-element 202 may be externally connected with the micro-electromechanical systems (MEMS) device 200 using a mechanical coupling 212. The actuator 208 is coupled with the movable MEMS element 204 initially and then optionally coupled with the movable noise-cancelling element 202. The movable noise-cancelling element 202 and the actuator 208 address the same periodic electrical signal with opposite phase differences. The movable noise-cancelling element 202 may set a specific vibration amplitude to cancel noise generated in the unencapsulated micro-electromechanical system (MEMS) device 200.

The movable noise-cancelling element 202 may obtain electrical signals that are 180 degrees out of phase from at least one of the controller or the electrical source (V1 and V2) that is controlled by the controller. For example, the actuator 208 obtains an electrical signal (V1) and the movable noise-cancelling element 202 obtains an electrical signal (V2), where V1=V₀ (sin θ) and V2=V₀ (sin θ+180°). The electrical signal (V1) and the electrical signal (V2) may enable the actuator 208 and the movable noise-cancelling element 202 to produce a specific vibration amplitude and periodicity to cancel noise generated in the micro-electromechanical system (MEMS) device 200.

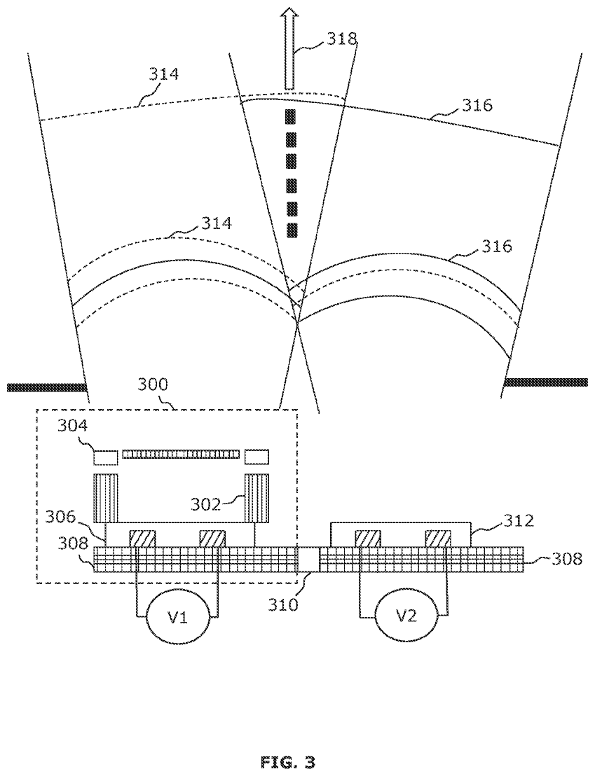

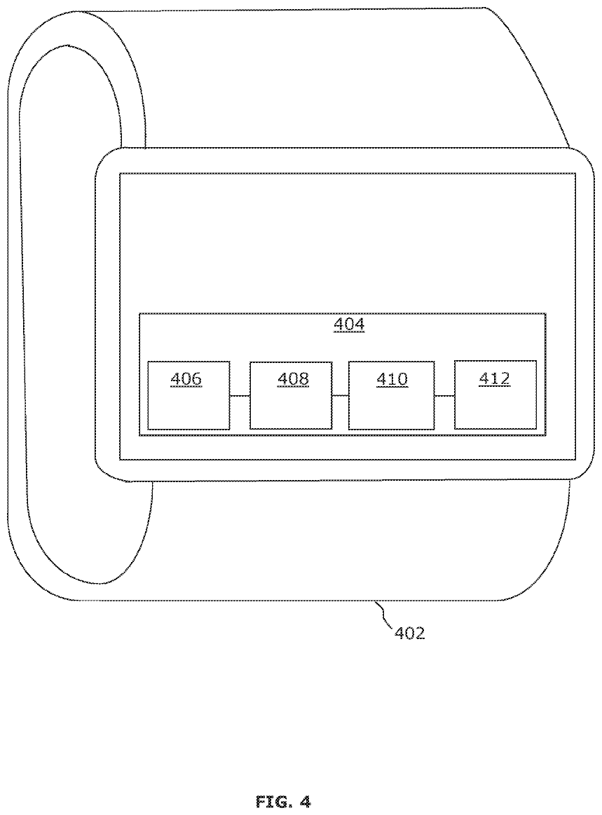

FIG. 3 is a schematic illustration of noise (air oscillation) cancellation by a micro-electromechanical systems (MEMS) device 300 in accordance with an embodiment of the present disclosure. The micro-electromechanical system (MEMS) device 300 includes a movable MEMS element 304, an actuator 306, a controller and a movable noise-cancelling element 312. The actuator 306 is operable to move the movable MEMS element 304. The controller controls the actuator 306 to cause the controlled movement of the movable MEMS element 304. The movable noise-cancelling element 312 is arranged to be driven under the control of the controller to produce anti-phase noise to cancel noise caused by oscillation of the movable MEMS element 304.

The movable MEMS element 304 may include a μ-mirror chip that is placed near to the actuator 306 using distance holders 302. The actuator 306 may include a mirror actuation device (MAD), and the MAD may be a piezoelectric device. The actuator 306 obtains electrical signals from at least one of the controller or an electrical source that is controlled by the controller. The controller, the movable MEMS element 304, the actuator 306 and the movable noise-cancelling element 312 are here shown as being formed on a common semiconductor substrate 308, although this configuration is optional. The movable noise-cancelling element 312 is optionally mechanically decoupled from the micro-electromechanical system (MEMS) device 300 by means of a mechanical decoupling arrangement 310.

The movable noise-cancelling element 312 obtains electrical signals which are 180 degrees out of phase from at least one of the controller or an electrical source that is controlled by the controller. For example, the actuator 306 obtains an electrical signal (V1) and the movable noise-cancelling element 312 obtains an electrical signal (V2), where V1=V₀ (sin θ) and V2=V₀ (sin θ+180°). The electrical signal (V1) and the electrical signal (V2) cause the actuator 306 to move the movable MEMS element 304 to produce the noise waves 314 and cause the movable noise-cancelling element 312 to produce anti-phase noise 316 which cancel each other at an annihilation region 318. The noise generated in the micro-electromechanical system (MEMS) device 300 is cancelled using the anti-phase noise produced by the movable noise-cancelling element 312.

The movable MEMS element 304 may be encapsulated using a wafer-level packaging technique (WLP technique). The WLP technique optionally provides an hermetic vacuum with wafer-level encapsulation. The movable MEMS element 304 optionally includes an optical element which generate the noise in the micro-electromechanical systems (MEMS) device 300. The optical element optionally includes a scanning mirror or a piezoelectric element (PE). The movable noise-cancelling element 312 oscillates to produce anti-phase noise to cancel the noise generated by the micro-electromechanical system (MEMS) device 300. The movable noise-cancelling element 312 adjusts amplitude, frequency and phase as necessary to produce anti-phase noise to cancel the noise from the movable MEMS element. The noise generated in the micro-electromechanical system (MEMS) device 300 is detected using a noise detection element, for example, a microphone. The noise detection element provides information to the controller which drives the noise cancellation element such as a MEMS element, for example, the movable noise-cancelling element 312.

FIG. 4 is a schematic illustration of an example wearable device 402 with a micro-electromechanical systems (MEMS) device 404 for cancelling a noise generated by oscillation of a movable micro-electromechanical system (MEMS) element 406 in accordance with an embodiment of the present disclosure. The wearable device 402 with the micro-electromechanical systems (MEMS) device 404 includes the movable MEMS element 406, an actuator 408, a controller 410 and a movable noise-cancelling element 412. The movable MEMS element 406 is coupled to the actuator 408. The controller 410 provides electrical signals to the actuator 408 for controlling the movement of the movable MEMS element 406. The movable noise-cancelling element 412 is connected with the controller 410. The controller 410 provides the electrical signals which are 180 degrees out of phase from the electrical signals provided to the actuator 408. The electrical signals provided to the movable noise-cancelling element 412 by the controller 410 enables the movable noise-cancelling element 412 to produce anti-phase noise to cancel noise caused by oscillation of the movable MEMS element 406.

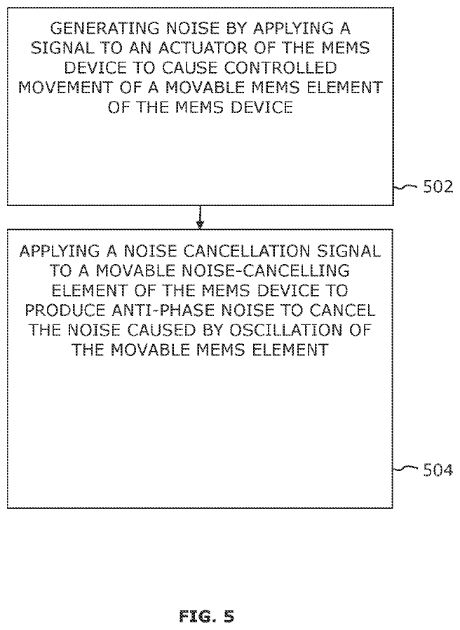

FIG. 5 is a flow diagram of a method of cancelling a noise for a micro-electromechanical systems (MEMS) device in accordance with an embodiment of the present disclosure. At step 502, noise is generated from a movable MEMS element of the MEMS device by applying a signal to an actuator of the MEMS device to cause controlled movement of the movable MEMS element. At step 504, anti-phase noise is produced by applying a noise cancellation signal to a movable noise-cancelling element of the MEMS device to cancel the noise caused by oscillation of the movable MEMS element. The signal applied to the actuator is optionally the same as the noise cancellation signal that is applied to the movable noise-cancelling element but 180 degrees out of phase. The noise cancellation signal is optionally produced by processing electrical signals that is produced based on the noise generated by the movement of the movable MEMS element using a transducer. The movable noise-cancelling element may be fabricated in parallel to the micro-electromechanical system (MEMS) device. The movable noise-cancelling element is optionally fabricated externally with respect to the actuator.

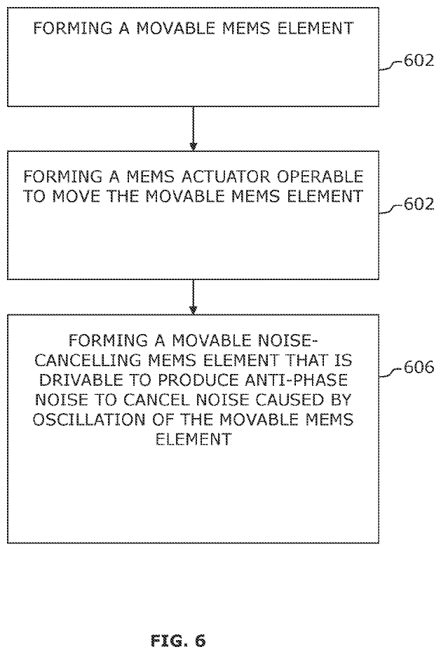

FIG. 6 is a flow diagram of an exemplary method of making a micro-electromechanical systems (MEMS) device with a noise cancelling function in accordance with an embodiment of the present disclosure. At step 602, a movable MEMS element is formed. At step 604, a MEMS actuator is formed and is operable to move the movable MEMS element. At step 606, a movable noise cancelling MEMS element is formed. The movable noise-cancelling MEMS element is driven to produce anti-phase noise to cancel noise caused by oscillation of the movable MEMS element. The three forming operations are performed on the same semiconductor substrate.

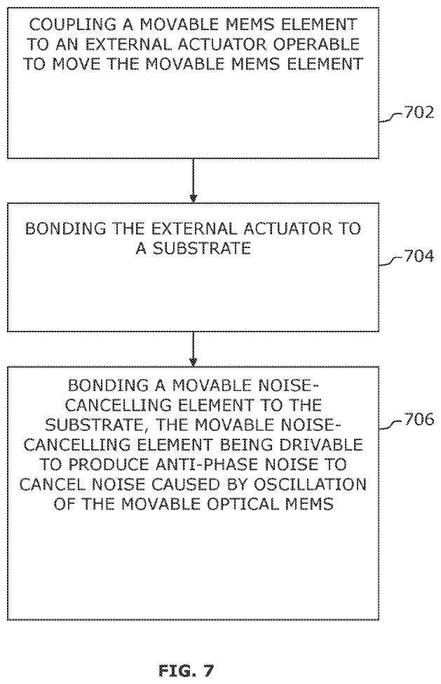

FIG. 7 is a flow diagram of an exemplary method of making a micro-electromechanical systems (MEMS) device with a noise cancelling function in accordance with an embodiment of the present disclosure. At step 702, a movable MEMS element is coupled to an external actuator which is operable to move the movable MEMS element. At step 704, the external actuator is bonded to a substrate. The substrate may configure to mechanically decouple the external actuator form the movable noise-cancelling element. At step 706, a movable noise-cancelling element is bonded to the substrate. The movable noise-cancelling element is driven to produce anti-phase noise to cancel noise caused by oscillation of the movable optical MEMS element.

The micro-electromechanical systems (MEMS) device according the present disclosure is optionally implemented in at least one of a virtual reality or augmented reality application, but the micro-electromechanical systems (MEMS) device may alternatively form part of a micro projector, mobile phone, or camera for example. The micro-electromechanical system (MEMS) device is optionally used in applications where sounds or vibrations of MEMS components (e.g. the movable MEMS element or the actuator) are likely to cause disturbance, particularly for example where the MEMS components are incorporated into a head mountable assembly, e.g. in AR/VR glasses, AR/VR helmets or similar. The micro-electromechanical system (MEMS) device reduces disturbance caused by noise and vibration from the moving MEMS element. Although this has particular significance in body-mounted and head-mounted equipment, such as Augmented reality or virtual reality (AR/VR) applications, it is also of benefit in free-standing equipment. The micro-electromechanical systems (MEMS) device may lead to reduced fatigue and greater user efficiency, since it is well known that ambient or background noise can have a detrimental effect on the ability to concentrate and to perform to a high level. The micro-electromechanical system (MEMS) device optionally used in construction areas (e.g. aircraft maintenance or repairing cars). The micro-electromechanical system (MEMS) device optionally used in medical applications e.g. by supporting a doctor or a surgeon when doing operations or human investigations. The micro-electromechanical system (MEMS) device optionally used in a laser scanner application for automotive, e.g. Lidar, heads-up display (HUD), head lights, is further possible. The micro-electromechanical systems (MEMS) device is optionally used in smartphones, projectors or cameras (3D or otherwise).

A technical problem in the prior art is resolved, where the technical problem is to improve the user experience of a device which has the fast-moving parts of the microelectromechanical system (MEMS).

Therefore, compared with the prior art, a micro-electromechanical systems (MEMS) device and a noise cancellation method are provided in the present disclosure to reduce the negative effects of vibrations caused by movement of a MEMS element. The micro-electromechanical system (MEMS) device according to the disclosure improves the user experience by achieving good cancelation of the noise generated by the movable MEMS element.

Although the present disclosure and its advantages have been described in detail, it should be understood that various changes, substitutions and alterations can be made herein without departing from the spirit and scope of the invention as defined by the appended claims.

1. A micro-electron-mechanical systems, MEMS, device including:
a movable MEMS element;
an actuator operable to move the movable MEMS element; and
a controller to control the actuator to cause controlled movement of the movable MEMS element;
the device additionally comprising:
a movable noise-cancelling element arranged to be driven under the control of the controller to produce anti-phase noise to cancel noise caused by oscillation of the movable MEMS element.

2. The MEMS device as claimed in claim 1, wherein the movable MEMS element and the actuator are formed in at least one of the following ways:
formed on a common semiconductor substrate,
packaged together in a common hermetic package, and the movable noise-cancelling element is located outside of the common hermetic package.

3. (canceled)

4. The MEMS device as claimed in claim 1, wherein
the movable MEMS element is a MEMS element of a MEMS structure, and the actuator is not an element of the MEMS structure that provides the movable MEMS element, or
the movable MEMS element is a MEMS element of a MEMS structure, the actuator is not an element of the MEMS structure that provides the movable MEMS element, and the movable noise-cancelling element and the actuator are mounted on a common substrate, or
the movable MEMS element is a MEMS element of a MEMS structure, the actuator is not an element of the MEMS structure that provides the movable MEMS element, the movable noise-cancelling element and the actuator are mounted on a common substrate, and the movable MEMS element is mounted on the actuator.

5. (canceled)

6. (canceled)

7. The MEMS device as claimed in claim 4, wherein the actuator is a piezoelectric element.

8. The MEMS device as claimed in claim 1, wherein the movable noise-cancelling element is at least one of the following:
a MEMS element,
a piezoelectric element.

9. The MEMS device as claimed in claim 1, wherein
the movable MEMS element and the actuator are formed on a common semiconductor substrate,
the movable noise-cancelling element is a MEMS element, and
the movable noise-cancelling element is also formed on the common semiconductor substrate.

10. (canceled)

11. The MEMS device as claimed in claim 7, wherein the movable noise-cancelling element is a piezoelectric element, and wherein the controller is configured to feed the actuator and the movable noise-cancelling element with the same electrical signals but 180 degrees out of phase.

12. The MEMS device as claimed in claim 1, in combination with a transducer that is arranged to provide the controller with signals derived from noise generated by the movable MEMS element.

13. The MEMS device as claimed in claim 12, wherein the controller is configured to generate signals to drive the movable noise-cancelling element based on the signals received from the transducer.

14. The MEMS device as claimed in claim 1, wherein the movable MEMS element is an optical element.

15. The MEMS device as claimed in claim 14,
in combination with a sound-confining enclosure which surrounds the MEMS device, the sound-confining enclosure defining an aperture through which light can pass from the movable optical MEMS element, or
in combination with a sound-confining enclosure which surrounds the MEMS device, the sound-confining enclosure defining an aperture through which light can pass from the movable optical MEMS element, and the arrangement being such that noise from the movable optical MEMS element and anti-phase noise from the movable noise-cancelling element can emerge from the sound-confining enclosure through the aperture to effect noise-cancellation in a direction in which light passes from the movable optical MEMS element through the aperture.

16. (canceled)

17. The MEMS device as claimed in claim 1, wherein the movable noise-cancelling element and the controller are configured to also produce anti-phase noise to cancel noise caused by movement of the actuator.

18. A wearable device including one or more MEMS devices as claimed in claim 1.

19. The wearable device of claim 17 configured as a Virtual Reality, VR, or Augmented Reality, AR, display.

20. A noise cancellation method for a micro-electromechanical system, MEMS, device, the method including:
generating noise by applying a signal to an actuator of the MEMS device to cause controlled movement of a movable MEMS element of the MEMS device; and
applying a noise cancellation signal to a movable noise-cancelling element of the MEMS device to produce anti-phase noise to cancel the noise caused by oscillation of the movable MEMS element.

21. The method of claim 20, wherein the signal applied to the actuator is the same as the noise cancellation signal that is applied to the movable noise-cancelling element but 180 degrees out of phase.

22. The method of claim 20, further comprising:
using a transducer to produce electrical signals based on the noise generated by movement of the movable MEMS element; and
processing the electrical signals produced by the transducer to produce the noise cancellation signal that is applied to the movable noise-cancelling element.

23. A method of making a micro-electromechanical system, MEMS, device including a noise-cancelling function, the method comprising:
forming a movable MEMS element;
forming a MEMS actuator operable to move the movable MEMS element; and
forming a movable noise-cancelling MEMS element that is drivable to produce anti-phase noise to cancel noise caused by oscillation of the movable MEMS element; wherein the three forming operations are performed on a common semiconductor substrate.

24. A method of making a micro-electromechanical system, MEMS, device including a noise-cancelling function, the method comprising:
coupling a movable MEMS element to an external actuator operable to move the movable MEMS element;
bonding the external actuator to a substrate; and
bonding a movable noise-cancelling element to the substrate, the movable noise-cancelling element being drivable to produce antiphase noise to cancel noise caused by oscillation of the movable optical MEMS element.

25. The method of claim 24, wherein the substrate is configured to mechanically decouple the external actuator form the movable noise-cancelling element.
